(19) United States
(12) Patent Application Publication
(10) Pub. No.: US 2013/0292245 A1
(43) Pub. Date: Nov. 7, 2013

(54) FE-PT-Based Ferromagnetic Sputtering Target and Method for Producing Same

(71) Applicants: Yuki Ikeda, Ibaraki (JP); Hideo Takami, Ibaraki (JP)

(72) Inventors: Yuki Ikeda, Ibaraki (JP); Hideo Takami, Ibaraki (JP)

(73) Assignee: JX NIPPON MINING & METALS CORPORATION, Tokyo (JP)

(21) Appl. No.: 13/995,890

(22) PCT Filed: Dec. 19, 2011
(86) PCT No.: PCT/JP2011/079327

§ 371 Date: Jul. 17, 2013

(30) Foreign Application Priority Data
Dec. 20, 2010 (JP) 2010-282771

(51) Int. Cl. C23C 14/34

(52) U.S. Cl. CPC C23C 14/3414; C23C 14/3407
USPC 204/298.13; 419/19

(57) ABSTRACT

A ferromagnetic sputtering target having a composition comprising 5 to 50 mol % of Pt, 5 to 15 mol % of SiO₂, 0.05 to 0.60 mol % of Sn, and Fe as the balance, wherein the Sn is contained in SiO₂ grains (B) dispersed in a metal base (A). Provided is a nonmagnetic grain-dispersed ferromagnetic sputtering target which can suppress abnormal electric discharge of the oxide that may cause particle generation during sputtering.

### TECHNICAL FILED

The present invention relates to a ferromagnetic sputtering target used for deposition of a magnetic thin film for a magnetic recording medium, in particular deposition of a magnetic recording layer for a hard disk employing the perpendicular magnetic recording system. The present invention also relates to a Fe—Pt-based ferromagnetic sputtering target which can suppress abnormal electric discharge of an oxide that may cause particle generation during sputtering.

In the field of magnetic recording represented by hard disk drives, Co—, Fe—, or Ni-based materials, which are ferromagnetic metals, are used as a material for a magnetic thin film which does recording. For example, in recording layers of hard disks employing the longitudinal magnetic recording system, Co—Cr-based or Co—Cr—Pt-based ferromagnetic alloys having Co as a main component are used.

Further, in recording layers of hard disks employing the recently-developed perpendicular magnetic recording system, composite materials composed of a Co—Cr—Pt-based ferromagnetic alloy having Co as a main component, and nonmagnetic inorganic grains are often used. Then, magnetic thin films for magnetic recording media such as hard disks are often manufactured by sputtering a ferromagnetic sputtering target consisting primarily of the above-mentioned materials in view of high productivity.

Meanwhile, the recording density of a magnetic recording medium is rapidly increasing every year, which is predicted to increase from a current surface density of 100 Gbit/in² to 1 Tbit/in² in the future. When a recording density reaches an order of Tbit/in², the size of a recording bit will be less than 10 nm. In that case, superparamagnetism due to thermal fluctuation may become a problem, and most likely, magnetic recording media currently used, including, for example, a material in which magnetocrystalline anisotropy is improved by adding Pt to a Co—Cr-based alloy, and a material in which magnetic coupling between magnetic grains is weakened by further adding B to the above material, may not be sufficient. This is because grains having a size of 10 mm or less which stably behave as ferromagnetic need to have higher magnetocrystalline anisotropy.

In view of the above, a FePt phase having the L1ₒ structure is attracting attention as a material for ultrahigh-density recording media. Further, the L1ₒ FePt phase may be a potential material suitably applied to a recording medium because it has an excellent corrosion resistance and oxidation resistance.

This FePt phase has an order-unorder transformation point at 1573 K, and shows the L1ₒ structure with a rapid ordering reaction even when quenching a common alloy from high temperature. However, the problem is that, in a case where a FePt thin film is manufactured by the gas-phase quenching methods such as sputtering and vapor deposition, only an unordered FePt phase in the fcc state is obtained because a solid phase is formed without passing through an order transformation point of the solid phase.

In order to use the FePt phase as a material for ultrahigh-density recording media, a technology needs to be developed in which ordered FePt nanograins are dispersed with high density in an oriented fashion as much as possible while they are magnetically isolated.

From this point of view, a granular magnetic recording medium has been proposed. This granular medium, which has a structure where magnetic fine grains are deposited in a nonmagnetic matrix such as an oxide, needs to have a structure in which the magnetic grains are magnetically insulated mutually through the intervention of a nonmagnetic substance.

For the granular magnetic recording medium and related known Documents, see Documents such as Patent Document 1, Patent Document 2, Patent Document 3 and Patent Document 4.

Moreover, the above magnetic recording layer is composed of a magnetic phase such as an Fe—Pt alloy, and a non-magnetic phase to isolate the magnetic phase, and a metal oxide is effective as one of the materials for the non-magnetic phase.

Many of these magnetic recording layers are formed by the sputtering deposition method. An attempt of sputtering a ferromagnetic sputtering target containing a metal oxide using a magnetron sputtering apparatus generally causes problems of an inadvertent release of the metal oxide during sputtering and abnormal electrical discharge starting at a void inherently included in the target, resulting in generation of particles (dust adhered on a substrate). In order to solve these problems, an enhanced adherence between a metal oxide and a matrix alloy, and further, a densified sputtering target are required.

Patent Document 1: Japanese Patent Laid-Open No. 2000-306228

Patent Document 2: Japanese Patent Laid-Open No. 2000-311329

Patent Document 3: Japanese Patent Laid-Open No. 2008-59733

Patent Document 4: Japanese Patent Laid-Open No. 2008-169464

### SUMMARY OF INVENTION

### Technical Problem

In general, in nonmagnetic grain-dispersed ferromagnetic sputtering targets such as a Co—Cr—Pt-oxide and a Fe-Pt-oxide, abnormal electric discharge may be caused because the oxides such as SiO₂, Cr₂O₃ and TiO₂ contained therein are insulators. Then, this abnormal electric discharge will cause a problem of particle generation during sputtering.

In view of the above problems, an object of the present invention is to suppress abnormal electric discharge of an oxide, and to decrease particle generation during sputtering caused by abnormal electric discharge.

Although a previous attempt to reduce the probability of abnormal electric discharge has been made by decreasing a grain size of the oxide, an acceptable particle level is becoming stricter as the recording density of a magnetic recording medium is improved. Therefore, an object of the present invention is to provide a further improved nonmagnetic grain-dispersed ferromagnetic sputtering target.

### Solution to Problem

After extensive studies for achieving the above object, the present inventors found that a target showing no abnormal electric discharge due to an oxide during sputtering and having less particle generation can be obtained by adjusting a composition and structure of the target.

Based on these findings, the present invention provides:

1) A ferromagnetic sputtering target having a composition comprising 5 to 50 mol % of Pt, 5 to 15 mol % of SiO₂, 0.05 to 0.60 mol % of Sn, and Fe as the balance, wherein the Sn is contained in SiO₂ grains (B) dispersed in a metal base (A).

The present invention further provides:

2) The ferromagnetic sputtering target according to 1), further comprising 5 to 15 mol % of one or more oxides selected from TiO₂, Ti₂O₃, Cr₂O₃, Ta₂O₅, Ti₅O₉, B₂O₃, CoO and Co₃O₄ in addition to the SiO₂, wherein the oxides are dispersed in the metal base (A) and the Sn is contained in the oxides.

The present invention further provides:

3) The ferromagnetic sputtering target according to any one of 1) to 2), comprising 0.5 to 10 mol % of one or more elements selected from Ru, B and Cu
4) The ferromagnetic sputtering target according to any one of 1) to 3), having a relative density of 97% or more.

The present invention further provides:

5) A method for producing a ferromagnetic sputtering target, the method comprising: preparing and mixing SiO₂ powder and SnO₂ powder or Sn powder to obtain a raw powder; further preparing Fe powder and Pt powder, or Fe-Pt alloy powder to be mixed with the raw powder so as to achieve a composition comprising 5 to 50 mol % of Pt, 5 to 15 mol % of SiO₂, 0.05 to 0.60 mol % of Sn, and Fe as the balance; and hot pressing the resulting mixed powder to disperse the SiO₂ grains (B) in the metal base (A), thereby obtaining a sintered compact having a structure in which the Sn is contained in the dispersed SiO₂ grains (B).

The present invention further provides:

6) The method for producing a ferromagnetic sputtering target according to 4), the method comprising: adding 5 to 15 mol % of one or more oxides selected from TiO₂, Ti₂O₃, Cr₂O₃, Ta₂O₅, Ti₅O₉, B₂O₃, CoO and Co₃O₄ in addition to the SiO₂ to disperse the oxides in the metal base (A), thereby obtaining a sintered compact having a structure in which the Sn is contained in the oxides.

The present invention further provides:

7) The method for producing a ferromagnetic sputtering target according any one of 4) to 5), the method comprising: adding 0.5 to 10 mol % of one or more elements selected from Ru, B and Cu, and then performing sintering.

### ADVANTAGEOUS EFFECTS OF INVENTION

The nonmagnetic grain-dispersed ferromagnetic sputtering target of the present invention prepared as described above can achieve a target, which does not generate abnormal electric discharge due to an oxide during sputtering and shows less particle generation.

Further, the target of the present invention has such the advantageous effects that abnormal electric discharge of an oxide can be reduced, particle generation during sputtering caused by abnormal electric discharge can be decreased, and cost improvement due to improved yields can be achieved.

### DESCRIPTION OF EMBODIMENTS

The main component of the ferromagnetic sputtering target according to the present invention is a metal having a composition comprising 5 to 50 mol % of Pt, 5 to 15 mol % of SiO₂, 0.05 to 0.60 mol % of Sn, and Fe as the balance. Each amount of Pt and Fe is an effective amount for a ferromagnetic sputtering target, i.e., for conferring properties of a ferromagnetic thin film.

These are components required as a magnetic recording medium, and their compounding proportions can vary within the ranges described above. In any of these cases, the properties as an effective magnetic recording medium can be maintained.

In a case where SiO₂ is added to a Fe—Pt-based ferromagnetic material, SiO₂ is usually present as grains in a sintered sputtering target. Because SiO₂ is an insulator, arcing may be induced in a case where SiO₂ is present alone. For this reason, according to the present invention, Sn, which has electrical conductivity, is introduced into SiO₂ to lower electric resistance so that abnormal electric discharge due to the oxide is suppressed.

The reason why the amount of SiO₂ is in the range between 5 mol % and 15 mol % inclusive is that the properties as a granular magnetic recording medium may be lost when an additive amount is outside the range.

The addition of Sn is effective in both cases of singe addition and compound addition. Note that single addition means an addition of SnO₂ powder or Sn powder while compound addition means an addition of a mixed powder of SiO₂ powder and SnO₂ powder or a mixed powder of SiO₂ powder and Sn powder.

The effective additive amount is in the range between 0.05 and 0.60 mol %. When it is less than the lower limit, there is no effect for conferring conductivity on SiO₂. When it is above the upper limit, magnetic properties of a sputter film are affected and desired properties may not be obtained.

In addition to the SiO₂, 5 to 15 mol % of one or more oxides selected from TiO₂, T1₂O₃, Cr₂O₃, Ta₂O₅, Ti₅O₉, B₂O₃, CoO and Co₃O₄ can be contained.

These oxides may be dispersed in the metal base (A), and Sn may be contained in these oxides in a similar way as the SiO₂. Depending on types of the required ferromagnetic films, these oxides can be suitably selected for addition. The additive amount described above is an effective amount to exert an effect of addition.

Furthermore, in the ferromagnetic sputtering target according to the present invention, 0.5 to 10 mol % of one or more elements selected from Ru, B and Cu can be added. These are elements to be added if necessary in order to improve properties as a magnetic recording medium. The additive amount described above is an effective amount to exert an effect of addition.

The ferromagnetic sputtering target according to the present invention preferably has a relative density of 97% or higher. It is generally known that a target having a higher density can reduce an amount of particle generated during sputtering.

High density is also preferred in the present invention. In the present invention, a relative density of 97% or higher can be achieved.

In the present invention, the relative density is a value obtained by dividing a measured density of a target by a calculated density (also called a theoretical density). The calculated density is a density when assuming that components of a target are present in a mixture without diffused or reacted with each other, and is calculated with the following formula.

Formula: calculated density=sigma (molecular weight of component×molar ratio of component)/Σ (molecular weight of component×molar ratio of component/literature density of component);

wherein Σ means getting the sum for every components of the target.

A target prepared as described above can achieve a target, which does not show arcing (abnormal electric discharge) due to an oxide during sputtering and shows less particle generation.

Further, as described above, the target has such an advantageous effect that the addition of Sn can confer electric conductivity on SiO₂ grains to prevent the development of abnormal electric discharge, thereby reducing the amount of particle generation which causes decreased yields.

The ferromagnetic sputtering target according to the present invention can be produced by the powder metallurgy method. In this case, first, a powder of each metal element is prepared, and, if necessary, a powder of an additive metal element is further prepared. For these powders, a powder having a maximum grain size of 20 μm or less is desirably used. Further, an alloy powder of these metals may be prepared instead of a powder of each metal element. In that case, a maximum grain size is also desired to be 20 μm or less.

On the other hand, when it is too small, a problem may arise that the component composition fails to fall into the range due to promoted oxidation. Therefore, more preferably, the grain size is 0.1 μm or more.

Then, the metal powders and alloy powders are weighed to give a desired composition, and then mixed and ground using a known technique such as a ball mill. In a case where an oxide powder other than SiO₂ is to be added, it may be mixed with the metal powders at this stage. An oxide powder having a maximum grain size of 5 μm or less is desirably used. On the other hand, when it is too small, it is more susceptible to agglomeration. Therefore, more desirably, a powder having a size of 0.1 μm or more is used.

Further, for a mixer, a planetary-screw mixer or a planetary-screw mixing agitator is preferred. Moreover, taking into account an issue of oxidation during mixing, mixing is preferably performed under an inert gas atmosphere.

Further, a method comprising: preparing and mixing SiO₂ powder and SnO₂ powder or Sn powder to obtain a raw powder; and further preparing Fe powder and Pt powder to be mixed with the raw powder so as to achieve a composition comprising 5 to 50 mol % of Pt, 5 to 15 mol % of SiO₂, 0.05 to 0.60 mol % of Sn, and Fe as the balance, is effective. At this stage, Fe—Pt alloy powder may be mixed.

The ferromagnetic sputtering target according to the present invention can be produced by molding and sintering the resulting powder using a vacuum hot press device, and cutting it into a desired shape.

In the present invention, it is important to disperse SiO₂ grains (B) in a metal base (A) and to obtain a sintered compact having a structure in which the Sn is contained in the dispersed SiO₂ grains (B).

The added Sn or SnO₂ is preferentially contained into the SiO₂ grains dispersed in the metal base in the sintered target to decrease the electric resistance of the SiO₂ grains. The electric resistance after addition can be 5.5×10¹⁶ Ω·cm or less.

The electric resistance exceeds than 5.5×10¹⁶ Ω·cm when Sn or SnO₂ is not added, and it acts as an insulator, causing abnormal electric discharge. In contrast, the present invention can prevent causing this phenomenon and thereby significantly reduces the development of arcing (abnormal electric discharge).

The molding and sintering described above are not limited to hot pressing, but the plasma discharge sintering method and the hot isostatic sintering method may be used. For a holding temperature during sintering, the lowest temperature in a temperature range where a target is well densified is preferably used. Depending on a composition of the target, in many cases, it is in a range between 900 and 1200° C.

### EXAMPLES

The present invention will be described based on Examples and

Comparative Examples below. Note that Examples are merely illustrative and the present invention shall in no way be limited thereby. That is, the present invention is limited only by the claims, and shall encompass various modifications other than those included in Examples of the present invention.

### Example 1

In Example 1, a SiO₂ powder having a mean grain size of 1 μm and a SnO₂ powder having a mean grain size of 1 μm were weighed to give 95 wt % of the SiO₂ powder and 5 wt % of the SnO₂ powder, which are mixed in a ball mill for 1 hour to prepare a SiO₂-SnO₂ mixed powder as a raw powder. The mixed powder, a Pt powder having a mean grain size of 3 μm and an Fe powder having a mean grain size of 3 μm were weighed in a weight ratio of 24.80 wt % of the Fe powder, 69.56 wt % of the Pt powder and 5.64 wt % of the SiO₂-SnO₂ mixed powder to achieve a target composition of 50Fe-40Pt-10(SiO₂-SnO₂) (mol %).

Then, the Fe powder, the Pt powder and the SiO₂-SnO₂ mixed powder were sealed, together with zirconia balls as grinding media, in a ball mill pot with a 10 liters capacity, and it was rotated for 20 hours for mixing.

A carbon mold was filled with the resulting mixed powder, and hot pressed in a vacuum atmosphere under the following conditions: temperature of 1100° C.; a holding time of 2 hours; and a pressure of 30 MPa, to obtain a sintered compact.

This was further subjected to cutting work with a lathe to obtain a disk-shaped target with a diameter of 180 mm and a thickness of 7 mm.

Sputtering was performed using this target. As a result, the number of particle generation under the steady state was 2.8. Further, the relative density was 98.5%, indicating that a high-density target higher than 97% was obtained.

In order to measure electric resistance for a SiO₂-SnO₂ mixed powder, 95 wt % of a SiO₂ powder having a mean grain size of 1 μm and 5 wt % of a SnO₂ powder having a mean grain size of 1 μm were also sealed in a ball mill pot with a 10 liters capacity, and it was rotated for 1 hour for mixing. A carbon mold was filled with the resulting mixed powder, and hot pressed in a vacuum atmosphere under the following conditions: temperature of 1100° C.; a holding time of 3 hours; and a pressure of 30 MPa, to obtain a sintered compact. Electric resistance was measured to be 4.0×10¹⁶ Ω·cm in this case.

### Comparative Example 1

In comparative example 1, as raw powders, a Pt powder having a mean grain size of 3 μm, an Fe powder having a mean grain size of 3 μm and a SiO₂ powder having a mean grain size of 1 μm were prepared. These powders were weighed in a weight ratio of 24.94 wt % of the Fe powder, 69.69 wt % of the Pt powder and 5.37 wt % of the SiO₂ powder to achieve a target composition of 50Fe-40Pt-10SiO₂ (mol %).

Then, these powders were sealed, together with zirconia balls as grinding media, in a ball mill pot with a 10 liters capacity, and it was rotated for 20 hours for mixing.

Next, a carbon mold was filled with the resulting mixed powder, and hot pressed in a vacuum atmosphere under the following conditions: temperature of 1100° C.; a holding time of 2 hours; and a pressure of 30 MPa, to obtain a sintered compact. This was further processed with a lathe to obtain a disk-shaped target with a diameter of 180 mm and a thickness of 7 mm.

Sputtering was performed using this target. As a result, the number of particle generation under the steady state increased to 6.7. Note that the relative density was 98.0%.

### Example 2

In Example 2, a SiO₂ powder having a mean grain size of 1 μm and a SnO₂ powder having a mean grain size of 1 μm are weighed to give 95 wt % of the SiO₂ powder and 5 wt % of the SnO₂ powder, which are mixed in a ball mill for 1 hour to prepare a SiO₂-SnO₂ mixed powder as a raw powder. The mixed powder, a Pt powder having a mean grain size of 3 μm, an Fe powder having a mean grain size of 3 μm, a Cu powder having a mean grain size of 5 μm and a Cr₂O₃ powder having a mean grain size of 3 μm were weighed in a weight ratio of 60.97 wt % of the Fe powder, 14.20 wt % of the Pt powder, 9.25 wt % of the Cu powder, 11.06 wt % of the Cr₂O₃ powder and 4.52 wt % of the SiO₂-SnO₂ mixed powder to achieve a target composition of 75Fe-5Pt-10Cu-5Cr₂O₃-5(SiO₂-SnO₂) (mol %).

Next, the Fe powder, the Pt powder, the Cu powder, the Cr₂O₃ powder and the SiO₂-SnO₂ mixed powder were sealed, together with zirconia balls as grinding media, in a ball mill pot with a 10 liters capacity, and it was rotated for 20 hours for mixing.

A carbon mold was filled with the resulting mixed powder, and hot pressed in a vacuum atmosphere under the following conditions: temperature of 1100° C.; a holding time of 2 hours; and a pressure of 30 MPa, to obtain a sintered compact.

This was further subjected to cutting work with a lathe to obtain a disk-shaped target with a diameter of 180 mm and a thickness of 7 mm.

Sputtering was performed using this target. As a result, the number of particle generation under the steady state was 3.1. Further, the relative density was 97.8%, indicating that a high-density target higher than 97% was obtained.

### Comparative Example 2

In Comparative Example 2, as raw powders, a Pt powder having a mean grain size of 3 μm, an Fe powder having a mean grain size of 3 μm, a Cu powder having a mean grain size of 5 μm, a Cr₂O₃ powder having a mean grain size of 3 μm and a SiO₂ powder having a mean grain size of 1 pm were prepared. These powders were weighed in a weight ratio of 61.06 wt % of the Fe powder, 14.22 wt % of the Pt powder, 9.26 wt % of the Cu powder, 11.08 wt % of the Cr₂O₃ powder and 4.38 wt % of the SiO₂ powder to achieve a target composition of 75Fe-5Pt-10Cu-5Cr₂O₃-5SiO₂ (mol %). Sn is not included in this component composition.

Then, these powders were sealed, together with zirconia balls as grinding media, in a ball mill pot with a 10 liters capacity, and it was rotated for 20 hours for mixing.

Next, a carbon mold was filled with the resulting mixed powder, and hot pressed in a vacuum atmosphere under the following conditions: temperature of 1100° C.; a holding time of 2 hours; and a pressure of 30 MPa, to obtain a sintered compact. This was further processed with a lathe to obtain a disk-shaped target with a diameter of 180 mm and a thickness of 7 mm.

Sputtering was performed using this target. As a result, the number of particle generation under the steady state increased to a worsened value of 10.0. Note that the relative density was 97.4%. Note that the cases of addition of SiO₂ and Cr₂O₃ are shown in the above Examples. However, even in a case where one or more oxides selected from TiO₂, Ti₂O₃, Ta₂O₅, Ti₅O₉, B₂O₃, CoO and Co₃O₄ are further added, an effect similar to a case where SiO₂ is added can be obtained.

Further, in Example 2 showing a case where Cu was further added, particle generation or decreased density was not caused thereby as long as the amount was within the predetermined range. Then, it is found that in a case where 0.5 to 10 mol % of one or more elements selected from Ru, B and Cu are contained, properties as a magnetic recording medium can be further improved.

Although no detailed descriptions are given in particular, it is found that a Fe—Pt—C-oxide can also suppress abnormal electric discharge due to an oxide by using the method according to the present invention, and has an affect which leads to decreased particles.

### INDUSTRIAL APPLICABILITY

The present invention can achieve, by adjusting the structure of a ferromagnetic sputtering target, suppression of abnormal electric discharge due to an oxide during sputtering, and less particle generation. Therefore, in a case where a target according to the present invention is used, stable electric discharge can be obtained when sputtering is performed with a magnetron sputtering apparatus. Further, the target of the present invention has such the advantageous effects that abnormal electric discharge of an oxide can be reduced, particle generation during sputtering caused by abnormal electric discharge can be decreased, and cost improvement due to improved yields can be achieved. Therefore, it is useful as a ferromagnetic sputtering target used for depositing a magnetic thin film of a magnetic recording medium, in particular a recording layer of hard disk drive.

1. A ferromagnetic sputtering target having a composition comprising 5 to 50 mol % of Pt, 5 to 15 mol % of SiO₂, 0.05 to 0.60 mol % of Sn, and Fe, wherein the Sn is contained in SiO₂ grains (B) dispersed in a metal base (A).

2. The ferromagnetic sputtering target according to claim 1, further comprising 5 to 15 mol % of one or more oxides selected from TiO₂, Ti₂O₃, Cr₂O₃, Ta₂O₅, Ti₅O₉, B₂O₃, CoO and Co₃O₄ in addition to the SiO₂, wherein the oxides are dispersed in the metal base (A) and the Sn is contained in the oxides.

3. The ferromagnetic sputtering target according to claim 2, further comprising 0.5 to 10 mol % of one or more elements selected from Ru, B and Cu.

4. The ferromagnetic sputtering target according to claim 3, wherein the sputtering target has a relative density of 97% or more.

5. A method for producing a ferromagnetic sputtering target, the method comprising the steps of: preparing and mixing SiO₂ powder and SnO₂ powder or Sn powder to obtain a raw powder; further preparing Fe powder and Pt powder, or Fe-Pt alloy powder to be mixed with the raw powder so as to achieve a composition comprising 5 to 50 mol % of Pt, 5 to 15 mol % of SiO₂, 0.05 to 0.60 mol % of Sn, and Fe; and hot pressing the resulting mixed powder to disperse the SiO₂ grains (B) in the metal base (A), thereby obtaining a sintered compact having a structure in which the Sn is contained in the dispersed SiO₂ grains (B).

6. The method for producing a ferromagnetic sputtering target according to claim 5, further comprising the step of: adding 5 to 15 mol % of one or more oxides selected from TiO₂, Ti₂O₃, Cr₂O₃, Ta₂O₅, Ti₅O₉, B₂O₃, Co0 and Co₃O₄ in addition to the SiO₂ to disperse the oxides in the metal base (A), thereby obtaining a sintered compact having a structure in which the Sn is contained in the oxides.

7. The method for producing a ferromagnetic sputtering target according to claim 6, further comprising the step of:
adding 0.5 to 10 mol % of one or more elements selected from Ru, B and Cu, and then performing sintering.

8. The method for producing a ferromagnetic sputtering target according to claim 5, further comprising the step of: adding 0.5 to 10 mol % of one or more elements selected from Ru, B and Cu, and then performing sintering.

9. The ferromagnetic sputtering target according to claim 1, further comprising 0.5 to 10 mol % of one or more elements selected from Ru, B and Cu.

10. The ferromagnetic sputtering target according to claim 9, wherein the sputtering target has a relative density of 97% or more.

11. The ferromagnetic sputtering target according to claim 1, wherein the sputtering target has a relative density of 97% or more.
